(19) United States
(12) Patent Application Publication
(10) Pub. No.: US 2011/0001641 A1
(43) Pub. Date: Jan. 6, 2011

(54) Electronic Device Equipped with Programmable Key Layout and Method for Programming Key Layout

(75) Inventor: LI-SHEN TUNG, HSINCHU (TW)

Correspondence Address: Chih Feng Yeh, 188 Old Castle Point Rd., Wappingers Falls, NY, 12590-7069, US

(73) Assignee: MITAC TECHNOLOGY CORPORATION, HSINCHU (TW)

(21) Appl. No.: 12/495,816

(22) Filed: Jul. 1, 2009

(51) Int. Cl. H03M 11/00

(52) U.S. Cl. 341/23

(57) ABSTRACT

An electronic device equipped with programmable key layout in provided, which includes a microprocessor, a sensor point array assembly, and a memory module. The sensor point array assembly is electrically coupled to the microprocessor through an interface circuit. A plurality of sensor points is distributed over the sensor point array assembly. The memory module stores a keymap table, and at least a sensor point grid defined by a user and a key code corresponding to the sensor point grid are written into the keymap table. The sensor point grid includes at least one of the sensor points of the sensor point array assembly. When one or more of the sensor points of the sensor point array assembly is triggered, the microprocessor differentiates the key code corresponding to the sensor point grid including the triggered sensor point according to the keymap table in the memory module.

### BACKGROUND OF THE INVENTION

1. Field of the Invention

The present invention relates to keyboard of an electronic device, and more particularly, to an electronic device equipped with a programmable key layout and a method for programming the key layout of the electronic device.

2. Related Art

In a mechanical keyboard, every key includes a plastic key cap. The top of the key cap are marked with a character, a symbol, or a code. An elastic member and a sensor are disposed under the key cap. When the user presses the key cap, the sensor is triggered by the key cap and then sends a trigged signal to the electric device through a data transmission cable, so as to enter data or launch a data procession.

Furthermore, the configuration and the size of a key, the gap between two adjacent keys, and the arrangement of all the keys are determined and unchangeable when the keyboard had been manufactured. Take the common electronic devices, a desktop computer and a laptop computer, as illustrations. The arrangement of all the keys, namely the relative positions of all the keys, in a desktop computer is similar to that in a laptop computer. However, the size of the laptop computer is small compared with the size of the desktop computer. Therefore, the size of the keyboard is limited by the size of the laptop computer. In the laptop computer, the size of each key is small, the gap between two adjacent keys is narrow, and the user easily triggers more than one key simultaneously. Therefore, data input with the keyboard of a laptop computer is un-convenient.

R. 0. C. Taiwan Patent NO. 535101 disclosed a liquid crystal display (LCD) touch-controlled computer keyboard, which at least includes a LCD touch-controlled panel, a detection interface, and a keyboard base. The LCD touch-controlled panel has a display surface divided into multiple display blocks for displaying various types of input code. The detection interface is electrically coupled to the LCD touch-controlled panel through a circuit. The keyboard base covers the LCD touch-controlled panel and the detection interface, and has the display blocks of the LCD touch-controlled panel be exposed outside the keyboard base. Through displaying input codes, the LCD touch-controlled computer keyboard displays the corresponding input codes when the computer system changes the language system of the computer keyboard or the input method of the computer operation system, by the application of an input code display method.

R. 0. C. Taiwan patent NO. 445415 disclosed a keyboard-less and twin LCD portable computer, which includes a first LCD, a second LCD, and a switch device. The switch device is electrically coupled to the first and the second LCDs, so as to switch the first and the second LCDs from a normal mode to a read mode. In the normal mode, the first LCD is a touch controlled virtual keyboard while the second is a display device. In the read mode, both the first and the second LCDs are display devices.

R. 0. C. Taiwan patent NO. I244024 disclosed a keyboard for automatically adjusting gaps between keys, which detects the size of the palm of a user and then adjusts the displayed keys accordingly. The keyboard includes a detecting module, an adjusting module, and a display module. The detecting module detects the palm contour range, the adjusting module adjusts the display parameters of the keyboard, and the display module determines the configuration of the keyboard according to the parameters and displays the keyboard.

Furthermore, in a keyboard utilizing physical keys in the prior art, gaps exist between keys. It is easy for a foreign matter intruding into the keyboard through the gaps and waterproof is difficult to be achieved since the gaps exist. When elastic fatigue occurs in the elastic member disposed under a keycap of a key, the key is easily to be failure or jammed, therefore the user has to replace the keyboard.

Some of the electronic devices utilizing software virtual keyboard displayed in a single touch screen. Among the aforementioned electronic devices, the size of the keyboard is restricted by the size of the electronic devices. Due to the fact that proper ergonomic design can not be utilized, the user easily mis-touches other keys when touch a designated key. Therefore, it is un-convenient for a user to enter data with such a virtual keyboard. Some of the other provided on-screen small keyboard operated by a cursor display on the screen. However, it is also difficult to operate the on-screen small keyboard. Moreover, the on-screen small keyboard cuts the screen into multiple frames and reduces the visible range on the screen which is also un-convenient for the user.

### SUMMARY OF THE INVENTION

Through the electronic device and the method of the present invention, a user can define sensor points included in each sensor point grid and the correspondingly key codes in his/her preferred manner. Therefore, according to his/her preference and requirement, the user can adjust the proper size of a key (the amount of the sensor points included in a sensor point grid), gaps between the keys (gaps between the sensor point grid), and key lout (the key code corresponding to each sensor point grid). Moreover, multiple sensor point grids can be designed to the sensor points within a finger-width range, therefore the user can send key codes corresponding to multiple sensor point grids simultaneously by a single one touch.

Without physical keys and cover by a protection plate, the apparent design of the electronic device is enhanced. The protection plate is made of tempered glass, so that it would not be damaged when the user wipes the electronic device. Without physical keys, the gaps between keys do not exist in the present invention, and the problem that the foreign matter intrudes the gaps between the keys will not occurs in the present invention. In mechanical design, the waterproof issue is easy to be achieved and the material of the keys is not a consideration to the life-span of the keyboard.

Moreover, through the display panel, the users can look-and-feel the appearance of the keys and the three dimensions visual effect showing the keys being pressed. And displayed character can show the characters of one or more languages. Therefore, when the user operates the keyboard, the user can look at every character that he/she is going to enter, there is no on-screen small keyboard cutting the screen into multiple frames, so as to have the user to operate the keyboard conveniently and comfortably.

### BRIEF DESCRIPTION OF THE DRAWINGS

The present invention will become more fully understood from the detailed description given herein below for illustration only, and thus not limitative of the present invention, wherein:

FIG. 1 is a perspective view according to a first embodiment of the present invention;

FIG. 2 is a partial enlarged top view of a sensor point array assembly;

FIG. 3 is a block diagram according to the first embodiment of the present invention;

FIG. 4 is a keymap table;

FIG. 5 is flow chart according to the first embodiment of the present invention;

FIG. 6 is a partial enlarged top view of a sensor point array assembly;

FIG. 7 is a partial enlarged top view of a sensor point array assembly:

FIG. 8 is a block diagram according to a second embodiment of the present invention;

FIG. 9 is a partial enlarged top view of the sensor point array assembly;

FIG. 10 is flow chart according to the second embodiment of the present invention; and

FIG. 11 is a perspective view according to the second embodiment of the present invention.

### DETAILED DESCRIPTION OF THE INVENTION

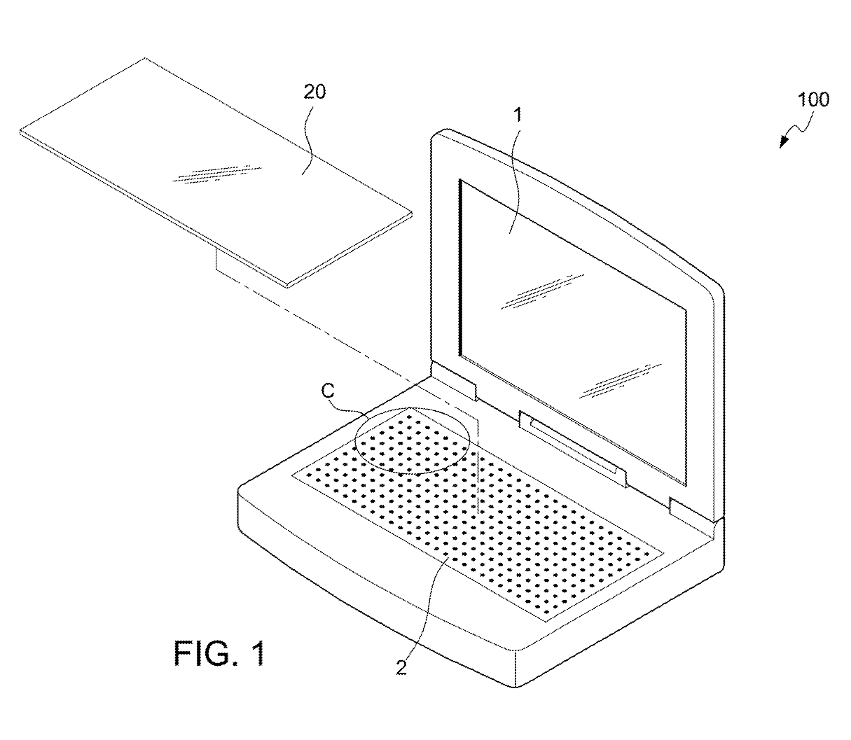

FIG. 1 is a perspective view according to a first embodiment of the present invention. As shown in FIG. 1, the electronic device 100 includes a monitor 1 and a sensor point array assembly 2. In the first embodiment, the electronic device 100 is a laptop computer in which the monitor 1 is well known in the prior art. A protection plate 20 is disposed over the sensor point array assembly 2. The protection plate 20 may be made of tempered glass, satisfying waterproof and dustproof demands. Moreover, the protection plate 20 protects the sensor point array assembly 2 from being damaged when the sensor point array assembly 2 is wiped.

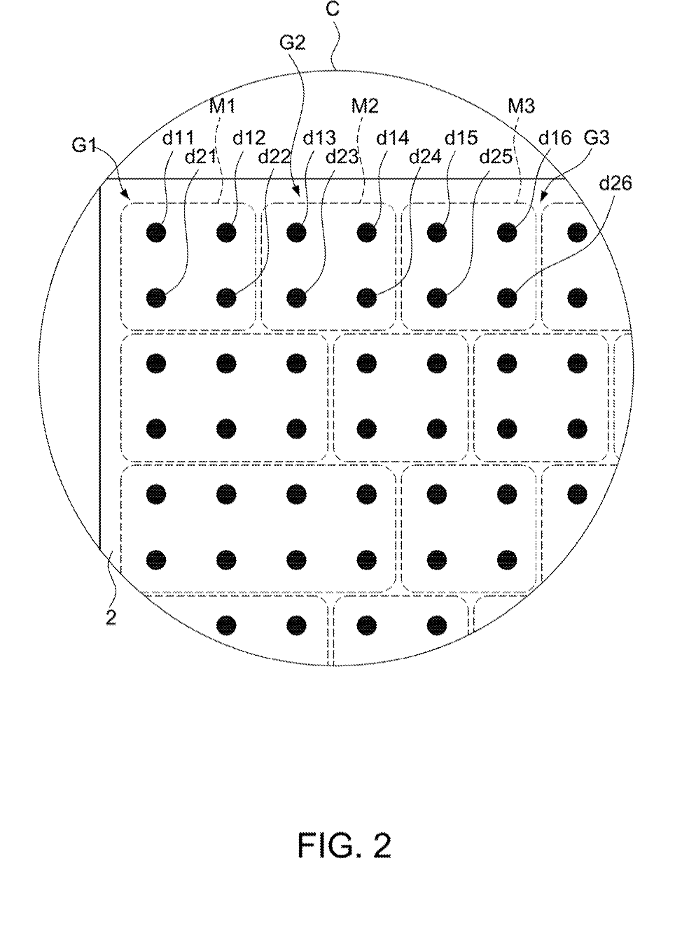

FIG. 2 is a partial enlarged top view of a sensor point array assembly 2. Referring to FIG. 1 and FIG. 2, in area C, a plurality of sensor points d11, d12, d13, d14, d15, d16, d21, d22, d23, d24, d25, d26 are distributed over the sensor point array assembly 2. (FIG. 2 is a schematic view for showing numbers of each sensor points). Each of the sensor points d11, d12, d13, d14, d15, d16, d21, d22, d23, d24, d25, and d26 can be a temperature sensor point or a pressure sensor points for detecting the variation of temperature or pressure.

The corresponding functions of the sensor points d11, d12, d13, d14, d15, d16, d21, d22, d23, d24, d25, d26 are defined by the user. In the first embodiment, the sensor points d11, d12, d21, d22 circumscribed by the mark area M1 are defined as a sensor point grid G1 by the user; the sensor points d13, d14, d23, d24 circumscribed by the mark area are defined as a sensor point grid G2; the sensor points d15, d16, d25, d26 circumscribed by the mark area M3 are defined as a sensor point grid G3. The function of the sensor point grid G1, G2, or G3 is similar to a key of a keyboard in the prior art.

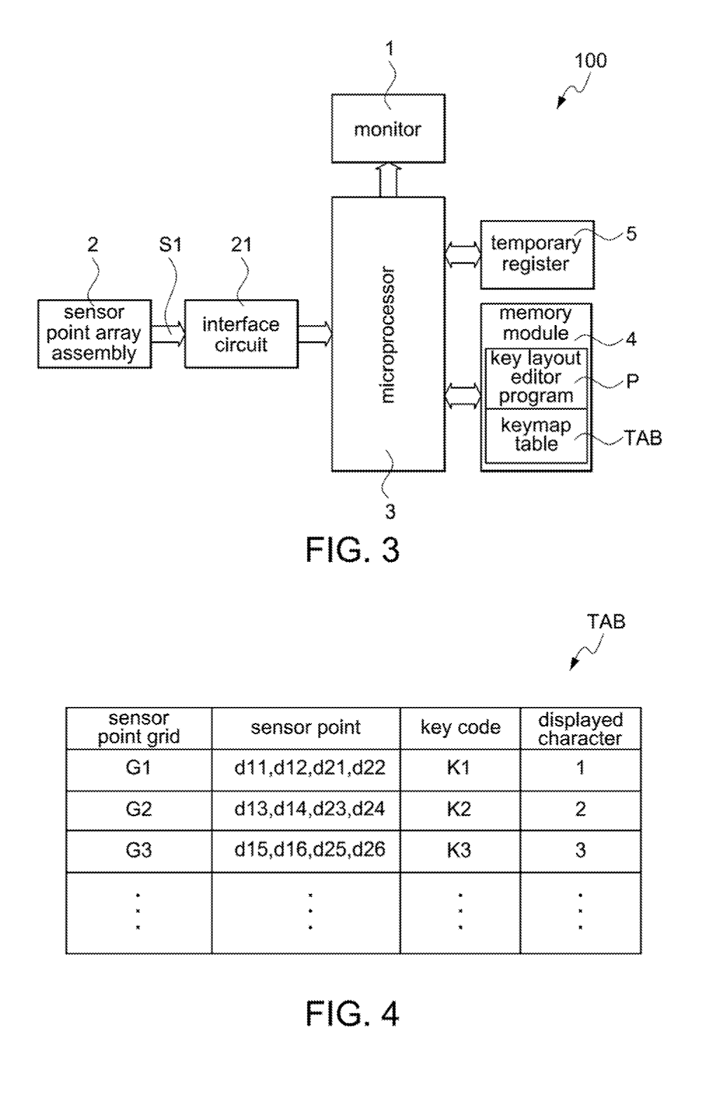

FIG. 3 and FIG. 4 are a block diagram and a keymap table according to the first embodiment of the present invention. The controlling circuit according to the first embodiment of the present invention includes a microprocessor 3, a memory module 4, and a temporary register 5. The microprocessor 3 is disposed in the electronic device 100. The microprocessor 3 is electrically coupled to the monitor 1, and is electrically coupled to the sensor point array assembly 2 through an interface circuit 21. The microprocessor 3 is also electrically coupled to the memory module 4 and the temporary register 5.

The memory module 4 stores a key layout editor program P and a keymap table TAB. The memory module 4 can be ordinary writeable-erasable memory module, such as an Erasable Programmable Read-Only Memory module (EEPROM module) or a Flash memory module. Therefore, the user can update the content of the keymap table TAB in the memory module 4. The user can update keymap table TAB in the memory module 4 through a GUI or command-line application.

One or more sensor point grid G1, G2, G3 can be written into the keymap table TAB. The sensor points d11, d12, d21, d22 of sensor point array assembly 2 included in the sensor point grid G1, the sensor points d13, d14, d23, d24 of the sensor point array assembly 2 included in the sensor point grid G2, and the sensor points d15, d16, d25, d26 of the sensor point array assembly 2 included in the sensor point grid G3 are correspondingly written into the keymap table TAB.

Each of the sensor point grids G1, G2, G3 is defined to correspond to the key codes K1, K2, K3 respectively, and each of the sensor point grids G1, G2, G3 also corresponds to a displayed characters. The content of the key code K1, K2, or K3 can be a single character, a combination of plural characters, or function codes to launch specific function. The displayed character is similar to the symbol, the character, or the code marked on a key cap of a keyboard in the prior art. In general, the displayed character showing the character of one or more languages to indicate the content of the key code K1, K2, or K3.

When the sensor point d13 of the sensor point array assembly 2 is triggered by the user (assuming the user triggering the sensor point d13), the sensor point d13 sends a triggered signal S1 to the microprocessor 3 through the interface circuit 21. According to the keymap table TAB in the memory module 4, the microprocessor 3 differentiates the sensor point grid G2 including the triggered sensor point d13, and obtain the key code K2 corresponding to the sensor point grid G2. Then, the microprocessor 3 launches preset operation corresponding to the key code K2, for example, displaying the displayed character on the monitor.

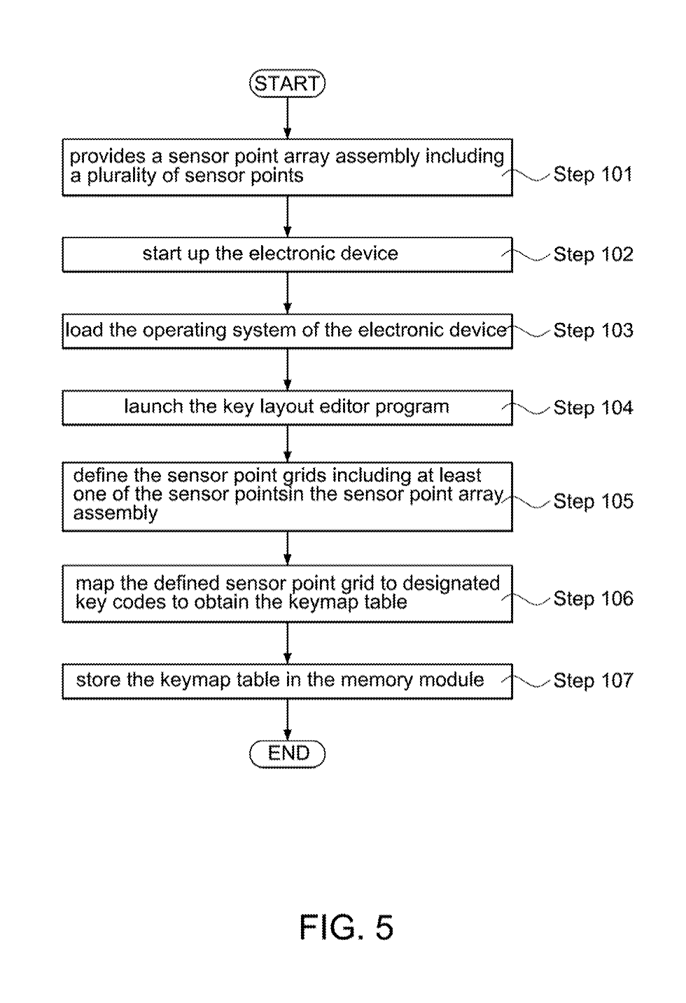

FIG. 5 is a flow chart according to the first embodiment of the present invention. Referring to FIG. 1 to FIG. 5, the detail of the flow chart is described here below.

Firstly, the electronic device 100 provides a sensor point array assembly 2 including a plurality of sensor points d11, d12, d13, d14, d15, d16, d21, d22, d23, d24, d25, d26 (Step 101), wherein the sensor points d11, d12, d13, d14, d15, d16, d21, d22, d23, d24, d25, d26 are distributed over the sensor point array assembly 2. Next, the electronic device 100 is started up (Step 102) to load the operating system of the electronic device 100 (Step 103). Then, the user can operate the electronic device 100 to launch the key layout editor program P stored in the electronic device 100 (Step 104). That is the microprocessor 3 loads and launches the key layout editor program P stored in the memory module 4. To accelerate the executed speed, the key layout editor program P can be loaded to the temporary register 5 when launching the key layout editor program P.

During the key layout editor program P is running, the user can edit the key layout through a GUI or command-line application, for example, editing the key layout displayed on the monitor 1 with a computer mouse. Through the key layout editor program P, the user defines the sensor point grids G1, G2, G3 including at least one of the sensor points d11, d12, d13, d14, d15, d16, d21, d22, d23, d24, d25 in the sensor point array assembly 2 (Step 105).

Then, the user maps the defined sensor point grids G1, G2, G3 to designated key codes K1, K2, K3 to obtain the keymap table TAB(Step 106). Finally, store the keymap table TAB in the memory module 4 (Step 107).

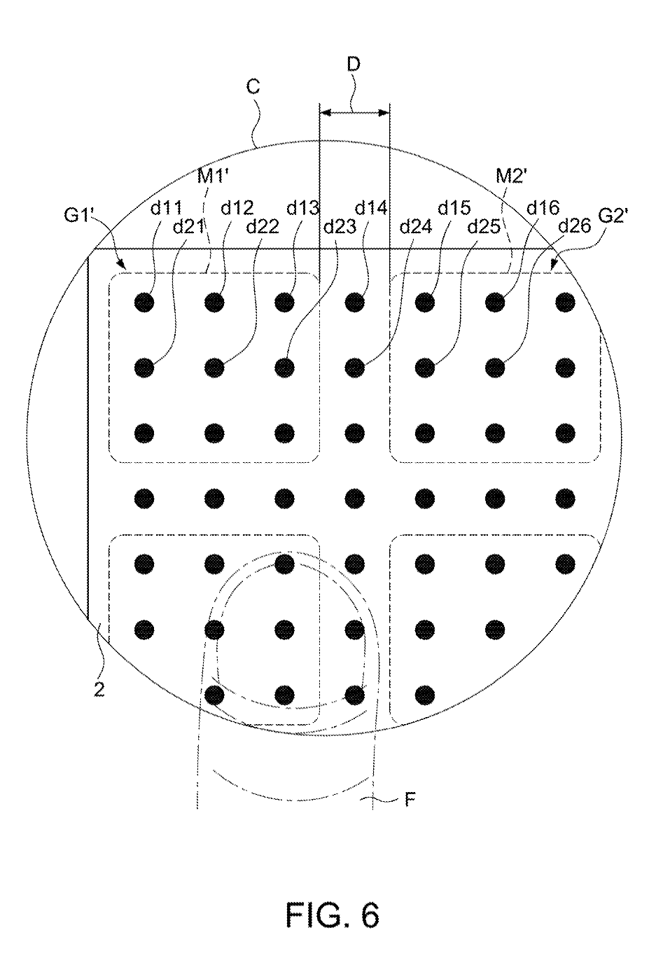

FIG. 6 is a partial enlarged top view of a sensor point array assembly. According to the user-preferred key layout, the user can re-edit the sensor point grid G1′ and the sensor point grid G2′, that is to change the circumscribed area of the mark area M1′ and the circumscribed area of the mark area M2′. Therefore, the measure of the sensor point grids G1′, G2′ is enlarged to meet the preference of the user. The gap D between the adjacent sensor point grids G1′, G2′ can also defined by the user, so as to prevent the finger F from triggering plural sensor point grids simultaneously.

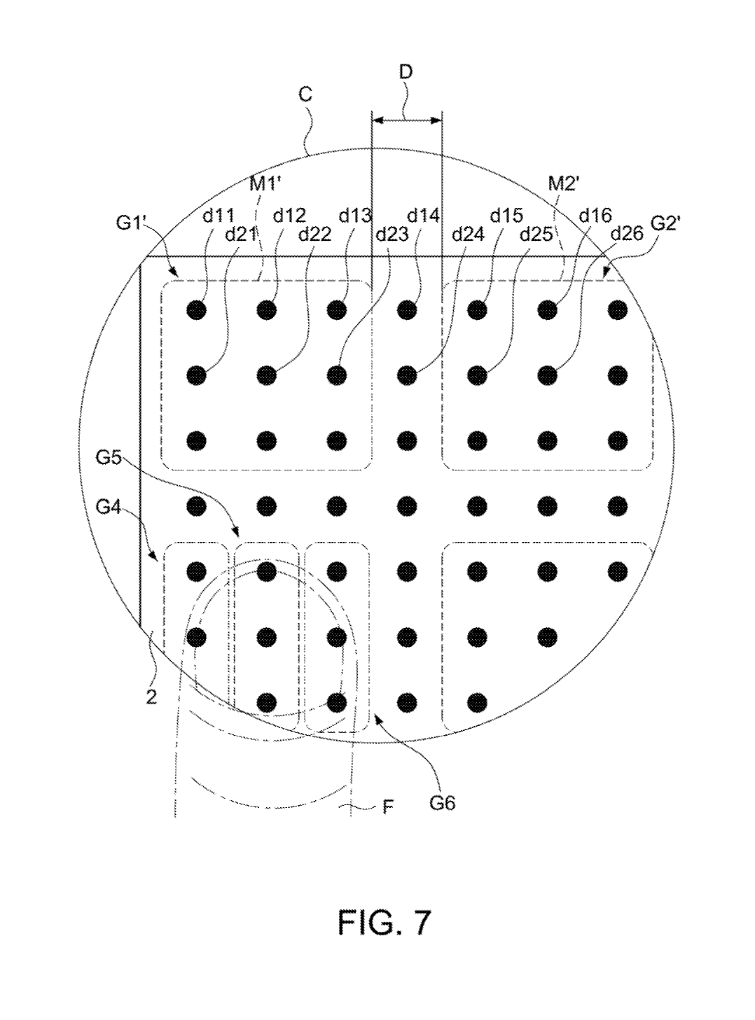

FIG. 7 is a partial enlarged top view of a sensor point array assembly. The user can define the sensor point grids G4, G5, G6 to smaller mark areas, for example, defining the sensor point grid G4 as the “Ctrl” key in the traditional keyboard, the sensor point grid G5 as the “Alt” key in the traditional keyboard, and the sensor point grid G6 as the “Del” key in the traditional keyboard. The user can define the width of the sensor point grid G4, G5, or G6 approximately the same as the width of the finger F, and the user can trigger the sensor point grids G4, G5, G6 simultaneously to launch the function of the combination of the “Ctrl” key, the “Alt”, and the “Del” key.

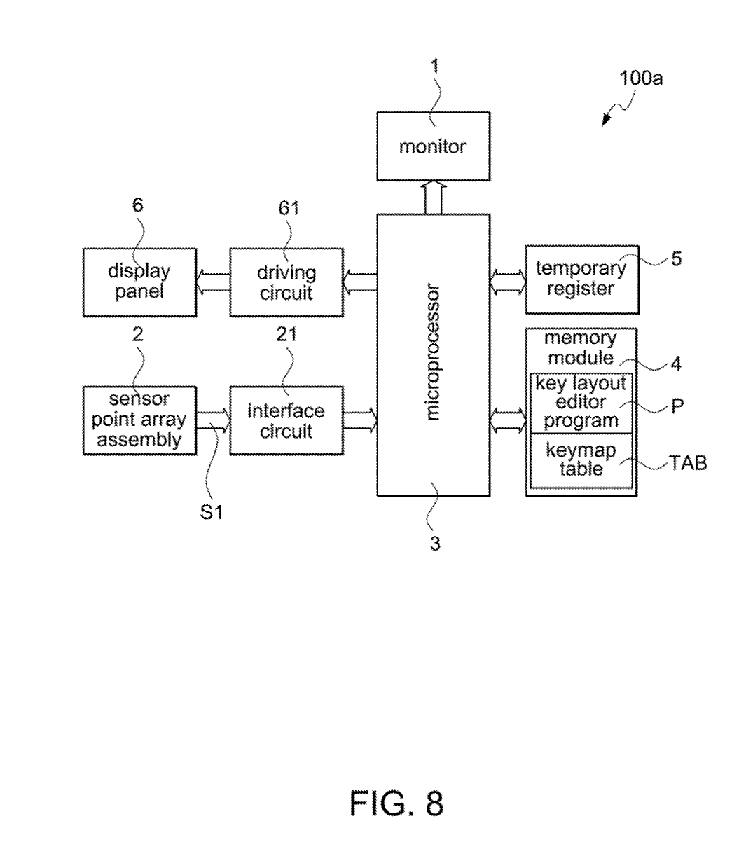

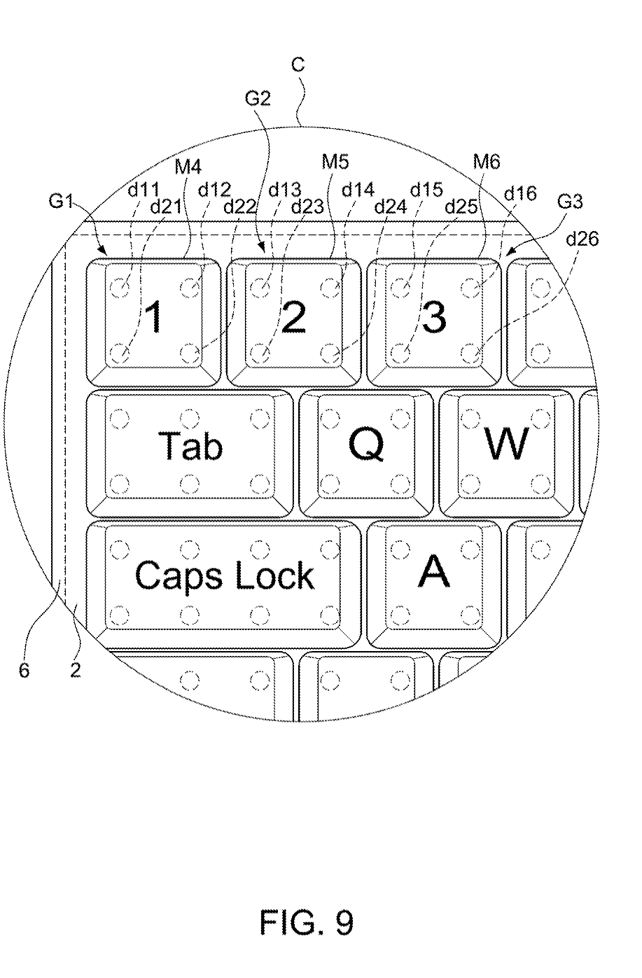

FIG. 8 and FIG. 9 are a block diagram and a partial enlarged top view of the sensor point array assembly according to a second embodiment of the present invention. The detail of the electronic device 100a is approximately the same as the detail of the electronic device 100 in the first embodiment. Therefore, the similar elements are given the same number for cross-referencing. The difference between the first and the second embodiments is that the electronic device 100a further includes a display panel 6 disposed correspondingly to the sensor point array assembly 2, and electrically coupled to the microprocessor 3 through a driving circuit 61.

The display panel 6 displays the mark areas M4, M5, M6 corresponding to the sensor point grids G1, G2, G3, to show the structural lines representing physical keys. Therefore, the triggered range of the sensor point grid G1, G2, or G3 is clearly revealed, and the sensor point grid G1, G2, or G3 has the sense of three dimensions. Moreover, the display panel 6 can further display the visual effect showing the key being pressed by the user. The display panel 6 also display the displayed characters written into the keymap table TAB (As shown in FIG. 4) to inform the user of the corresponding function of the sensor point grid G1, G2, or G3. When the user operates the electronic device, the user can see every character that he/she enters, the frame being cut is not a problem any more.

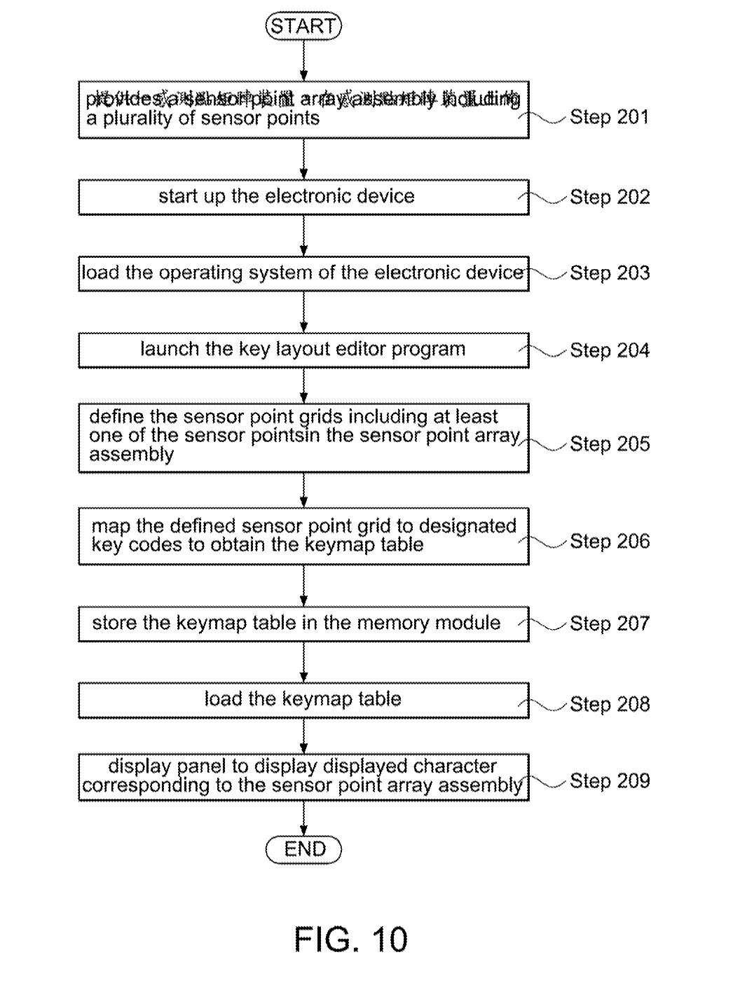

FIG. 10 is flow chart according to the second embodiment of the present invention. Firstly, the electronic device 100a provides a sensor point array assembly 2 including a plurality of sensor points d11, d12, d13, d14, d15, d16, d21, d22, d23, d24, d25, and d26 distributed over the sensor point array assembly (Step 201). Next, the electronic device 100a is started up (Step 202) to load the operating system of the electronic device 100a (Step 203). Then, the user can operate the electronic device 100a to launch the key layout editor program P (Step 204).

During the key layout editor program P is running, the user defines the sensor point grids G1, G2, G3 including at least one of the, sensor points d11, d12, d13, d14, d15, d16, d21, d22, d23, d24, d25, d26 in the sensor point array assembly 2 (Step 205).

Then, the user maps the defined sensor point grids G1, G2, G3 to designated key codes K1, K2, K3 and maps the defined sensor point grids G1, G2, G3 to corresponding displayed characters, so as to obtain the keymap table TAB (Step 206). Finally, store the keymap table TAB in the memory module 4 (Step 207). Then, the electronic device 100a loads the keymap table TAB(Step 208) and drives the display panel 6 to display displayed character corresponding to the sensor point array assembly 2 (Step 209) for the user to trigger.

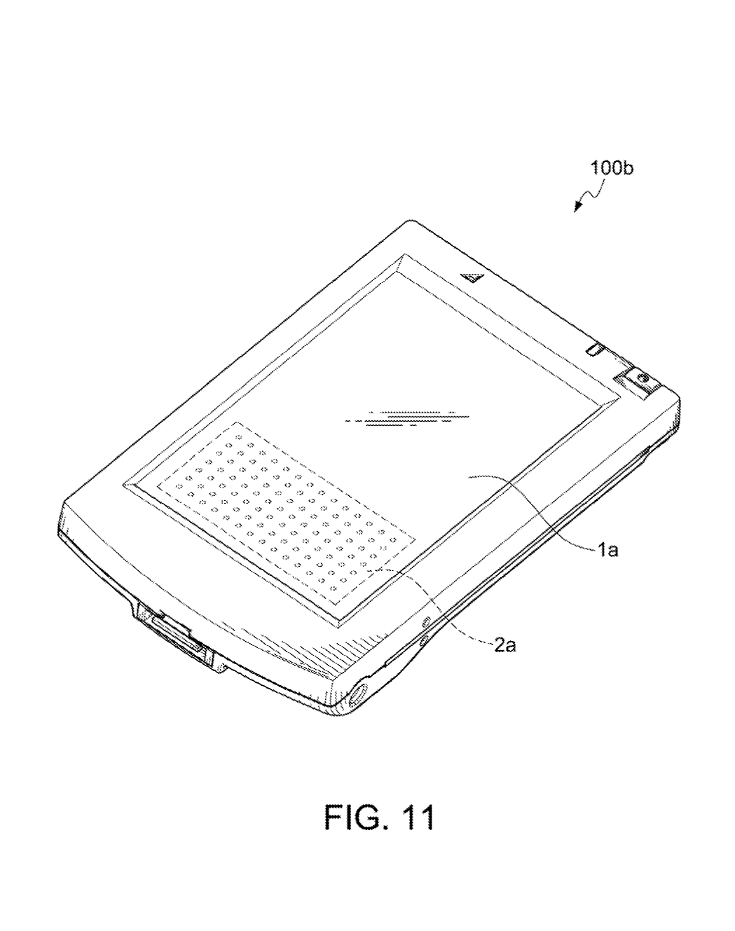

FIG. 11 is a perspective view according to the second embodiment of the present invention. As shown in FIG. 1, the electronic device 100b is a personal digital assistant (PDA), and the sensor point array assembly 2a is disposed corresponding to the monitor 1a of the electronic device 100b. Therefore, the display panel 6 (as shown in FIG. 9) is not required wherein the monitor 1a directly display the visual effect such as mark area, the displayed character. etc.

According to one or more embodiments of the present invention, the electronic device equipped with programmable key layout and method for programming the key layout is useful. Additional advantages and modifications will readily occur to those proficient in the relevant fields. The invention in its broader aspects is therefore not limited to the specific details and representative embodiments shown and described herein. Accordingly, various modifications may be made without departing from the spirit or scope of the general inventive concept as defined by the appended claims and their equivalents.

What is claimed is:

1. An electronic device equipped with programmable key layout, comprising:
a microprocessor;
a sensor point array assembly, electrically coupled to the microprocessor through an interface circuit, and a plurality of sensor points distributed over the sensor point array assembly;
a memory module, storing a keymap table, and at least a sensor point grid defined by a user and a key code corresponding to the sensor point grid written into the keymap table, wherein the sensor point grid includes at least one of the sensor points of the sensor point array assembly;
wherein the electronic device equipped with programmable key layout is arranged such that when one or more of the sensor points of the sensor point array assembly is triggered, the triggered sensor point sends a triggered signal to the microprocessor through the interface circuit and then the microprocessor differentiates the key code corresponding to the sensor point grid including the triggered sensor point according to the keymap table in the memory module.

2. The electronic device equipped with programmable key layout as claimed in claim 1, further comprising a display panel electrically coupled to the microprocessor and disposed correspondingly to the sensor point array assembly.

3. The electronic device equipped with programmable key layout as claimed in claim 2, wherein the display panel displays a displayed character corresponding to the key code in the keymap table.

4. The electronic device equipped with programmable key layout as claimed in claim 2, wherein the display panel displays mark area corresponding to the sensor point grid defined by the user.

5. The electronic device equipped with programmable key layout as claimed in claim 1, wherein each of the sensor points is a temperature sensor point or a pressure sensor point.

6. The electronic device equipped with programmable key layout as claimed in claim 1, wherein a protection plate is disposed over the sensor point array assembly.

7. The electronic device equipped with programmable key layout as claimed in claim 1, wherein the electronic device is a laptop computer.

8. The electronic device equipped with programmable key layout as claimed in claim 1, wherein the electronic device is a personal digital assistant.

9. A method for programming key layout of an electronic device, comprising the following steps:
(a) providing a sensor point array assembly including a plurality of sensor point distributed over the sensor point array assembly;
(b) launching a key layout editor program;
(c) defining at least one sensor point grid including at least one of the sensor points of the sensor point array assembly;
(d) mapping the defined sensor point grid to a designated key code to obtain a keymap table.

10. The method for programming key layout of an electronic device as claimed in claim 9, further comprising a step for storing the keymap table after the step (d).

11. The method for programming key layout of an electronic device as claimed in claim 9, wherein the step (d) comprising that mapping the defined sensor point grid to a displayed character.

12. The method for programming key layout of an electronic device as claimed in claim 11, further comprising a step for displaying the displayed character corresponding to the sensor point array assembly after the step (d).
